(19) United States
(12) Patent Application Publication
(10) Pub. No.: US 2025/0336456 A1
(43) Pub. Date: Oct. 30, 2025

(54) FLASH MEMORY DEVICE AND PROGRAM METHOD THEREOF

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/095,040

(22) Filed: Mar. 31, 2025

(30) Foreign Application Priority Data
Apr. 26, 2024 (TW) 113115798

(51) Int. Cl. G11C 16/34; G11C 16/10

(52) U.S. Cl. CPC G11C 16/3459; G11C 16/102

(57) ABSTRACT

A flash memory device and a program method thereof are provided. The program method includes following. A program operation is performed on multiple cell groups in sequence. When a target memory cell group of the memory cell groups fails a program verification, one or more program verification cycles are performed on the target memory cell group. The target memory cell group is divided into M portions, and M is a positive integer greater than 1. It is determined whether the program verification cycle performed on the target memory cell group is the first program verification cycle. When the first program verification cycle is performed on the target memory cell group, the M portions are programmed in sequence.

### CROSS-REFERENCE TO RELATED APPLICATION

This application claims the priority benefit of Taiwan application serial no. 113115798, filed on Apr. 26, 2024. The entirety of the above-mentioned patent application is hereby incorporated by reference herein and made a part of this specification.

### BACKGROUND

### Technical Field

The disclosure relates to a control technology for a memory device, and more particularly, to a flash memory device for reducing time taken to perform a program operation and a program method thereof.

### Description of Related Art

Compared to the NAND flash memory device, the NOR flash memory device requires a longer time to perform program/erase operations. However, the NOR flash memory device may provide a complete address and data bus, thus allowing access to any memory cell on the NOR flash memory device. Therefore, how to reduce the time for performing the program operation on the NOR flash memory device has become one of the important issues in the art.

### SUMMARY

The disclosure provides a flash memory device and a program method thereof, which may dynamically adjust the number of memory cells being programmed at the same time in a program verification cycle, thereby reducing the time taken to perform a program operation.

A flash memory device in the disclosure includes a memory array and a memory control circuit. The memory array has multiple memory cell groups. A memory control circuit is coupled to the memory array and configured to perform a program operation on the memory cell groups in sequence. When a target memory cell group of the memory cell groups fails a program verification, the memory control circuit performs one or more program verification cycles on the target memory cell group. The target memory cell group is divided into M portions, and M is a positive integer greater than 1. The memory control circuit determines whether the program verification cycle performed on the target memory cell group is the first program verification cycle. When the first program verification cycle is performed on the target memory cell group, the memory control circuit programs the M portions in sequence.

A program method of a flash memory device in the disclosure includes the following. A program operation is performed on multiple memory cell groups in sequence. When a target memory cell group of the memory cell groups fails a program verification, one or more program verification cycles are performed on the target memory cell group. The target memory cell group is divided into M portions, and M is a positive integer greater than 1. It is determined whether the program verification cycle performed on the target memory cell group is the first program verification cycle. When the first program verification cycle is performed on the target memory cell group, the M portions are programmed in sequence.

Based on the above, in the flash memory device and the program method thereof according to the disclosure, when the first program verification cycle is performed on the target memory cell group, only one portion of the target memory cell group may be programmed at a time in sequence. In this way, the number of memory cells being programmed at the same time in the program verification cycle may be dynamically adjusted, thereby reducing the time taken to perform a program operation.

In order for the aforementioned features and advantages of the disclosure to be more comprehensible, embodiments accompanied with drawings are described in detail below.

### BRIEF DESCRIPTION OF THE DRAWINGS

FIG. 1 is a schematic view of a flash memory device according to an embodiment of the disclosure.

FIGS. 2 and 3 are flow charts of steps of a program method of a flash memory device according to some embodiments of the disclosure.

### DETAILED DESCRIPTION OF DISCLOSED EMBODIMENTS

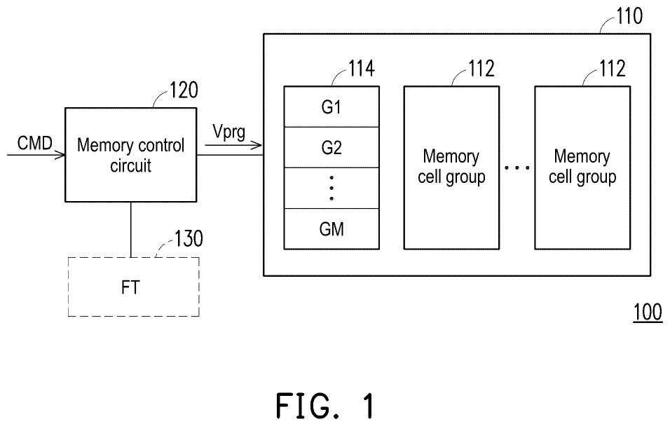

Referring to FIG. 1, a flash memory device 100 according to an embodiment of the disclosure is, for example, a NOR type, and includes a memory array 110 and a memory control circuit 120. The memory array 110 includes multiple memory cell groups 112. Each of the memory cell groups 112 includes multiple memory cells to be programmed into a specific data pattern. The memory cell is, for example, an ETOX structure. In the embodiment of the disclosure, the numbers of memory cell groups 112 and memory cells are not limited.

The memory control circuit 120 is coupled to the memory array 110. The memory control circuit 120 may be configured to perform a program operation on all the memory cell groups 112 in sequence. Specifically, the memory control circuit 120 may select a target memory cell group 114 from the memory cell groups 112 in the memory array 110 for the program operation according to a received selection command CMD. In this embodiment, the target memory cell group 114 may be divided into M portions G1 to GM, where M is a positive integer greater than 1. For example, each of the portions G1 to GM may correspond to 16 bits. The portion G1 includes 16 memory cells corresponding to the highest 16 bits in the target memory cell group 114. The portion G2 includes 16 memory cells corresponding to the 16 bits immediately following the bits of the portion G1 in the target memory cell group 114. The rest may be derived by analogy. However, in the disclosure, sizes and the corresponding numbers of bits of each of the portions G1 to GM are not limited, and those skilled in the art may make appropriate adjustments according to actual requirements.

In addition to, for example, a state machine, a central processing unit, or other programmable general-purpose or special-purpose microprocessors, a digital signal processor, a programmable controller, an application-specific integrated circuit, a programmable logic device, or other similar devices or a combination of these devices, the memory control circuit 120 may also be a hardware circuit designed through hardware description languages or any other conventional design method of a digital circuit, and implemented through a field programmable gate array or a complex programmable logic device. In addition, although FIG. 1 shows that the memory control circuit 120 is located in the flash memory device 100, the memory control circuit 120 may also be a device independent of the flash memory device 100.

Optionally, the flash memory device 100 further includes a flag register 130. The flag register 130 is coupled to the memory control circuit 120, and is configured to store a frequency flag FT. Each time a program verification cycle is performed, the memory control circuit 120 may set an initial value of the frequency flag FT to a first value (e.g., “0”). In addition, although FIG. 1 shows that the flag register 130 is independent of the memory array 110 and the memory control circuit 120, the flag register 130 may also be integrated into the memory array 110 or the memory control circuit 120.

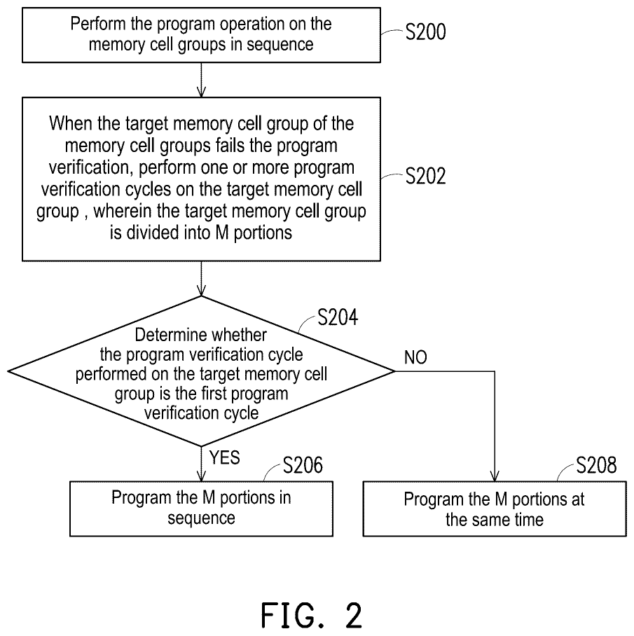

Referring to both FIGS. 1 and 2, a program method of a flash memory device in this embodiment is applicable to the flash memory device 100 in FIG. 1. Hereinafter, various steps of the program method according to the embodiment of the disclosure will be described with reference to various elements in the flash memory device 100.

First, in step S200, the memory control circuit 120 performs the program operation on the memory cell groups 112 in sequence. For example, the memory control circuit 120 may perform initialization and set one of all the memory cell groups 112 to be programmed in the memory array 110 (e.g., the first memory cell group) as the target memory cell group 114.

Then, the memory control circuit 120 may compare bit data (e.g., 32 bits) formed by the target memory cell group 114 with a specific data pattern (e.g., 32 bits) to determine whether the target memory cell group 114 passes a program verification. In more detail, in an example of the program verification, the memory control circuit 120 may determine whether a threshold voltage of each of the memory cells in the target memory cell group 114 complies with a specified range of each of bit values in the specific data pattern. For example, if the bit value in the data pattern is “0”, the threshold voltage of the corresponding memory cell is required to be greater than a preset program verification reference voltage. If the bit value in the data pattern is “1”, the threshold voltage of the corresponding memory cell is required to be less than the preset program verification reference voltage. The data patterns corresponding to each of the memory cell groups 112 may be the same or different.

Therefore, in step S202, if the target memory cell group 114 fails the program verification, the memory control circuit 120 performs one or more program verification cycles on the target memory cell group 114.

Next, in step S204, the memory control circuit 120 determines whether the program verification cycle performed on the target memory cell group 114 is the first program verification cycle. When the first program verification cycle is performed on the target memory cell group 114, in step S206, the memory control circuit 120 programs the M portions G1 to GM of the target memory cell group 114 in sequence. For example, the memory control circuit 120 may set an initial value of K to 1, and the memory control circuit 120 may determine whether the K-th portion GK of the target memory cell group 114 has one or more failed memory cells. If yes, the memory control circuit 120 may apply a program voltage Vprg to the failed memory cells of the K-th portion GK, and increment K (K=K+1) to proceed with the determination of the next portion. If not, the memory control circuit 120 directly increments K (K=K+1) to proceed with the determination of the next portion. In this embodiment, the so-called “failed memory cell” refers to the memory cell in the target memory cell group 114 that has failed the program verification. The program voltage Vprg includes voltages applied to a gate node, a drain node, a source node, and a well region of the failed memory cell, especially the voltage applied to the drain node. For example, the voltage applied to the gate node may be 9 volts, the voltage applied to the drain node may be 4 volts, and the voltages applied to the source node and the well region may be 0 volts. However, the disclosure is not limited thereto.

Moreover, the memory control circuit 120 may repeat the above steps of determining whether the K-th portion GK has one or more failed memory cells and incrementing K, thereby proceeding with the determination of the next portion until K is greater than M (all the portions G1 to GM have all been determined).

When the program verification cycle other than the first time (e.g., the second time, the third time, etc.) is performed on the target memory cell group 114, in step S208, the memory control circuit 120 programs the M portions G1 to GM of the target memory cell group 114 at the same time. Specifically, the memory control circuit 120 may apply the program voltage Vprg to the failed memory cells of all the M portions G1 to GM.

Observing an program operation on a NOR flash memory device, it requires a large number of currents and is limited by a pumping capability of the hardware circuit. In this embodiment, the so-called “pumping capability” refers to the number of bits for the memory control circuit 120 to perform a program pulse operation on the failed memory cells at the same time by using the program voltage Vprg (that is, the number of failed memory cells that may be applied with the program voltage Vprg at the same time).

In this embodiment, since the number of failed memory cells is the largest in the first program verification cycle, in the first program verification cycle, the memory control circuit 120 only applies the program voltage Vprg to the failed memory cells of the portion GK of the target memory cell group 114 at one time, thereby preventing the number of failed memory cells applied with the program voltage Vprg at the same time from exceeding the pumping capability.

Since the number of failed memory cells in the program verification cycle other than the first time decreases as the number of program verification cycles increases, in the program verification cycle other than the first time, the memory control circuit 120 may simultaneously apply the program voltage Vprg to the failed memory cells of all the M portions G1 to GM of the target memory cell group 114 at one time, thereby increasing a speed of the program verification. In this way, the time taken to perform the program operation may be reduced while taking into account limits of the pumping capability.

It is worth mentioning that the target memory cell group 114 in this embodiment is divided into the M portions G1 to GM according to a pumping capability of the flash memory device 100, for example. In other words, a magnitude of M may depend on the pumping capability of the flash memory device 100.

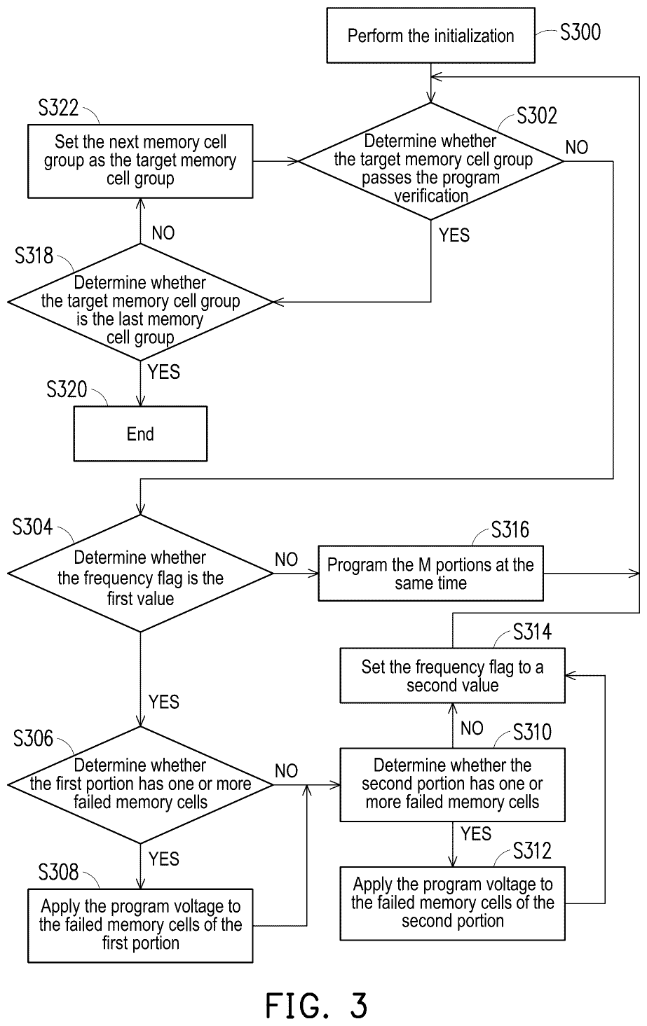

Hereinafter, the program method in the disclosure will be described in more detail with reference to the embodiment shown in FIG. 3. Referring to both FIGS. 1 and 3, the program method of the flash memory device in this embodiment is applicable to the flash memory device 100 in FIG. 1. Hereinafter, various steps of the program method according to the embodiment of the disclosure will be described with reference to various elements in the flash memory device 100. In this embodiment, descriptions that are the same as or similar to those of FIG. 2 will not be repeated in the following. In addition, in order to simplify the description, in this embodiment, it is assumed that the target memory cell group 114 is divided into two portions G1 to G2 (M is equal to 2).

First, in step S300, the memory control circuit 120 may perform the initialization and set the first memory cell group of all the memory cell groups 112 to be programmed in the memory array 110 as the target memory cell group 114.

Next, in step S302, the memory control circuit 120 determines whether the target memory cell group 114 passes the program verification. When the target memory cell group 114 fails the program verification, in step S304, the memory control circuit 120 determines whether the frequency flag FT stored in the flag register 130 is the first value (e.g., “0”). Specifically, the memory control circuit 120 may determine whether the program verification cycle performed on the current target memory cell group 114 is the first program verification cycle according to the frequency flag FT.

When the frequency flag FT is the first value, the memory control circuit 120 may determine that the program verification cycle performed on the current target memory cell group 114 is the first program verification cycle. Therefore, in step S306, the memory control circuit 120 determines whether the first portion G1 of the target memory cell group 114 has one or more failed memory cells. If yes, in step S308, the memory control circuit 120 applies the program voltage Vprg to the failed memory cells of the first portion G1, and then proceeds to S310. If not, the steps proceed directly to S310 after step S306.

In step S310, the memory control circuit 120 determines whether the second portion G2 of the target memory cell group 114 has one or more failed memory cells. If yes, in step S312, the memory control circuit 120 applies the program voltage Vprg to the failed memory cells of the second portion G2, and then proceeds to S314. If not, the steps proceed directly to S314 after step S310.

After the first program verification cycle is performed on the target memory cell group 114, in step S314, the memory control circuit 120 sets the frequency flag FT to a second value (e.g., “1”), and then returns to step S302 to proceed with the second program verification cycle.

When the memory control circuit 120 determines that the frequency flag FT stored in the flag register 130 is not the first value (but is the second value) in step S304, the memory control circuit 120 may determine the program verification cycle performed on the current target memory cell group 114 is the program verification cycle other than the first time (e.g., the second time, the third time, etc.). Therefore, in step S316, the memory control circuit 120 programs the two portions G1 to G2 of the target memory cell group 114 at the same time. Specifically, the memory control circuit 120 may apply the program voltage Vprg to the failed memory cells of all the two portions G1 to G2 at the same time, and then returns to step S302 to proceed with the next program verification cycle.

On the other hand, when the memory control circuit 120 determines that the target memory cell group 114 passes the program verification in step S302, in step S318, the memory control circuit 120 determines whether the target memory cell group 114 is the last memory cell group of all the memory cell groups 112 to be programmed. If yes, the steps proceed to S320 to end the program operation of the memory array 110. If not, in step S322, the memory control circuit 120 sets the next memory cell group of the memory cell groups 112 as the target memory cell group 114, and then proceeds to S302 to proceed with the program operation.

Based on the above, in the flash memory device and the program method thereof according to the disclosure, the number of memory cells being programmed at the same time in the program verification cycle may be dynamically adjusted. In this way, the time taken to the program operation may be reduced while taking into account the limits of the pumping capability.

What is claimed is:

1. A flash memory device, comprising:
a memory array having a plurality of memory cell groups; and
a memory control circuit coupled to the memory array and configured to perform a program operation on the memory cell groups in sequence,
wherein when a target memory cell group of the memory cell groups fails a program verification, the memory control circuit performs one or more program verification cycles on the target memory cell group,
wherein the target memory cell group is divided into M portions, and M is a positive integer greater than 1,
the memory control circuit determines whether the program verification cycle performed on the target memory cell group is the first program verification cycle, and when the first program verification cycle is performed on the target memory cell group, the memory control circuit programs the M portions in sequence.

2. The flash memory device according to claim 1, wherein when the first program verification cycle is performed on the target memory cell group, the memory control circuit sets an initial value of K to 1, where K is a positive integer, and determines whether a K-th portion of the target memory cell group has one or more failed memory cells, and if yes, the memory control circuit applies a program voltage to the one or more failed memory cells of the K-th portion.

3. The flash memory device according to claim 2, wherein the memory control circuit increments K to proceed with determination of a next portion, and repeats steps of determining whether the K-th portion has the one or more failed memory cells and incrementing K until K is greater than M.

4. The flash memory device according to claim 1, wherein when the program verification cycle other than the first time is performed on the target memory cell group, the memory control circuit programs the M portions at the same time.

5. The flash memory device according to claim 1, wherein the flash memory device further comprises a flag register configured to store a frequency flag, the flag register is coupled to the memory control circuit, and the memory control circuit determines whether the program verification cycle performed on the target memory cell group is the first program verification cycle according to the frequency flag.

6. The flash memory device according to claim 5, wherein when the frequency flag is a first value, the program verification cycle performed on the target memory cell group is the first program verification cycle, and when the frequency flag is a second value, the program verification cycle performed on the target memory cell group is the program verification cycle other than the first time.

7. The flash memory device according to claim 5, wherein the memory control circuit sets an initial value of the frequency flag to a first value, and after the first program verification cycle is performed on the target memory cell group, the memory control circuit sets the frequency flag to a second value.

8. The flash memory device according to claim 1, wherein when the target memory cell group passes the program verification, the memory control circuit determines whether the target memory cell group is a last memory cell group, and if not, the memory control circuit sets a next memory cell group as the target memory cell group to perform the program operation.

9. The flash memory device according to claim 1, wherein a magnitude of M depends on a pumping capability of the flash memory device.

10. A program method of a flash memory device, wherein the flash memory device comprises a memory array having a plurality of memory cell groups, and the program method comprises:
performing a program operation on the memory cell groups in sequence;
when a target memory cell group of the memory cell groups fails a program verification, performing one or more program verification cycles on the target memory cell group, wherein the target memory cell group is divided into M portions, and M is a positive integer greater than 1;
determining whether the program verification cycle performed on the target memory cell group is the first program verification cycle; and
when the first program verification cycle is performed on the target memory cell group, programming the M portions in sequence.

11. The program method according to claim 10, wherein programming the M portions in sequence comprises:
setting an initial value of K to 1, where K is a positive integer;
determining whether a K-th portion of the target memory cell group has one or more failed memory cells; and
if yes, applying a program voltage to the one or more failed memory cells of the K-th portion.

12. The program method according to claim 11, wherein programming the M portions in sequence further comprises:
incrementing K to proceed with determination of a next portion; and
repeating steps of determining whether the K-th portion has the one or more failed memory cells and incrementing K until K is greater than M.

13. The program method according to claim 10, further comprising:
when the program verification cycle other than the first time is performed on the target memory cell group, programming the M portions at the same time.

14. The program method according to claim 10, wherein the flash memory device further comprises a flag register configured to store a frequency flag, and determining whether the program verification cycle performed on the target memory cell group is the first program verification cycle comprises:
determining whether the program verification cycle performed on the target memory cell group is the first program verification cycle according to the frequency flag.

15. The program method according to claim 14, wherein when the frequency flag is a first value, the program verification cycle performed on the target memory cell group is the first program verification cycle, and when the frequency flag is a second value, the program verification cycle performed on the target memory cell group is the program verification cycle other than the first time.

16. The program method according to claim 14, further comprising:
setting an initial value of the frequency flag to a first value; and
after performing the first program verification cycle on the target memory cell group, setting the frequency flag to a second value.

17. The program method according to claim 10, further comprising:
when the target memory cell group passes the program verification, determining whether the target memory cell group is a last memory cell group; and
if not, setting a next memory cell group as the target memory cell group to perform the program operation.

18. The program method according to claim 10, wherein a magnitude of M depends on a pumping capability of the flash memory device.
